(19) United States
(12) Patent Application Publication
(10) Pub. No.: US 2005/0085005 A1
(43) Pub. Date: Apr. 21, 2005

(54) Low-cost electronic module and method for making same

(76) Inventor: Francois Droz, La Chaux-de-Fonds (CH)

Correspondence Address: Clifford W Browning;Woodard Emhardt Naughton Moriarty & McNett, Bank One Center Tower, 111 Monument Circle Suite 3700, Indianapolis, IN, 46204-5137, US

(21) Appl. No.: 10/497,822

(22) PCT Filed: Dec. 10, 2002
(86) PCT No.: PCT/IB02/05291

(30) Foreign Application Priority Data
Dec. 11, 2001 (CH) 2258/01

(51) Int. Cl. H01L 21/44

(52) U.S. Cl. 438/106

(57) ABSTRACT

The invention concerns a method for making highly cost-effective electronic modules. More particularly, said method is characterized by steps requiring simplified equipment enabling to manufacture rapidly a large amount of modules. The invention also aims at producing a reliable electronic module at a very low production cost. This is achieved by using a method for making an electronic module comprising an assembly of an insulating sheet (1) provided in the form of a tray for holding electronic components and including cells, at least an electronic component (3) placed in said cells (2), and a second insulating sheet. The method is characterized by the following steps: setting on a working surface a first insulating sheet formed by the cellular tray, said cells containing each at least an electronic component, superimposing the second insulating sheet on the first so as to close the cells containing the electronic component, cutting out the modules along an outline including at least a cell of the first insulating sheet.

This invention is part of the field of electronic modules and the manufacturing processes of said modules including a plurality of layers formed by superimposed sheets and at least one electronic component.

The invention concerns modules made by pressing and thermoforming of different successive layers, these modules including at least one electronic component defined here as an element such as a coil connected to a chip mainly called a transponder.

Modules known as smart cards, electronic labels or electronic circuits are made by assembling several sheets to form superimposed layers, namely a support called substrate, a conductive layer and protection sheets covering the module faces. The electronic component fixed on the substrate is connected to the conductive layer tracks. All these sheets are assembled either by hot gluing by means of a press, or by laminating.

Other modules are made by coating an electronic circuit with a binder. After the binder hardens, the faces of the module are, in general, covered by protection sheets acting as decoration.

The manufacturing processes of both module types quoted above include a large number of delicate, long, expensive operations requiring complex tooling. Furthermore, manufacturing very large series of modules requires a highly advanced rationalization of all the process with a minimal waste rate. The final products must be cheap and at the same time reliable until the end of their lifetime.

The aim of this invention is to offer an electronic modules manufacturing process with high profitability. More particularly, this method distinguished by steps needing simplified tooling allows fast manufacture of a very large quantity of modules.

This invention also has the aim of obtaining a reliable electronic module with a very low final cost.

This aim is reached by a method for manufacturing an electronic module having at least one electronic component transported on a tray made for the handling of electronic components and comprising cells, and a second insulating sheet characterized by the following steps:
placing the cells tray forming a first insulating sheet on a work surface, said cells containing each at least one electronic component,
superimposing the second insulating sheet onto the first in such a way as to close the cells containing the electronic component,
cutting the modules according to an outline including at least one cell of the first insulating sheet.

The electronic components, in general transponders, are delivered by the supplier in a conditioning whose base element is a tray constituted by a thermoformed insulating sheet. This tray, for transporting and handling the components, includes cells regularly distributed on its surface. In general, a cell contains one component.

The use of such an element for conditioning the components considerably reduces the number of operations of the module manufacturing process. In fact, the previous preparation steps of the first sheet, the handling and the positioning of the transponders, which can be fastidious, are no longer necessary. The first step of the method will consist thus in superimposing a second insulating sheet on the first one so that it closes all the cells that contain a component. Then, this assembly is hot pressed by means of a pressing plate applied onto the second insulating sheet to form a plate that incorporates a large number of components. This plate will be cut to obtain individual modules that include at least one component.

According to a embodiment of the process, a filling material, constituted for example of a resin, is introduced into the cells of the first insulating sheet to encapsulate the electronic component before placing the second sheet in position. The assembly may be hot pressed, or according to another embodiment, the second insulating sheet is applied by gluing only without pressing. In this case, the second sheet can include a layer of self-adherent material on the face to be applied onto the first insulating sheet. The modules obtained in this way without pressing and after cutting the tray keep the initial shape of a cell of the tray.

The final cutting of the modules is carried out by stamping, for example, according to an outline defined by that of a cell in the first insulating sheet where the electronic component is lodged. In the case of a module having several components, the outline of the module includes several cells.

This invention also has as object an electronic module comprising an assembly of a first insulating sheet, of at least one electronic component and a second insulating sheet characterized in that the first insulating sheet comes from a tray of electronic components handling including cells containing each at least one electronic component.

According to an embodiment, the module can include a layer of filling material between the first and second insulating sheet. This material, in general in the form of resin encapsulates the electronic component/s.

The invention will be better understood thanks to the following detailed description that refers to the attached drawings that are given as a non-limitative example, in which:

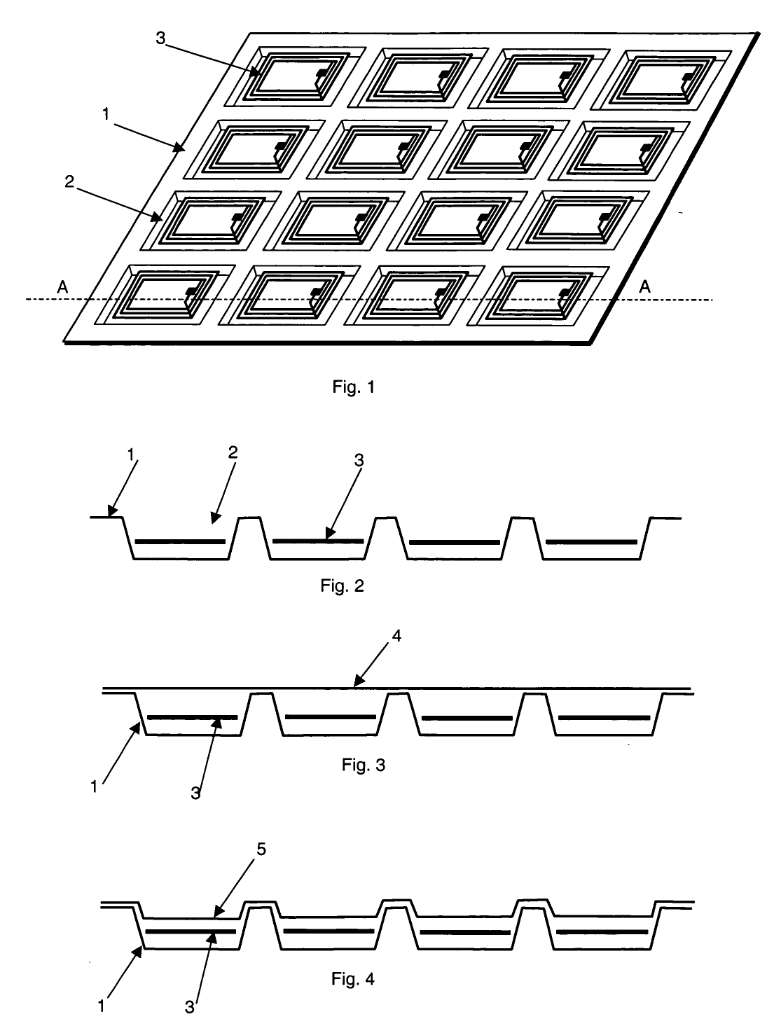

FIG. 1 represents a general view of a tray including cells containing each a transponder.

FIG. 2 represents a cutaway view of the plate containing the transponder.

FIG. 3 shows a view of a section of the tray containing the transponder with a second sheet closing the cells.

FIG. 4 shows an embodiment of FIG. 3 where the second sheet is thermoformed.

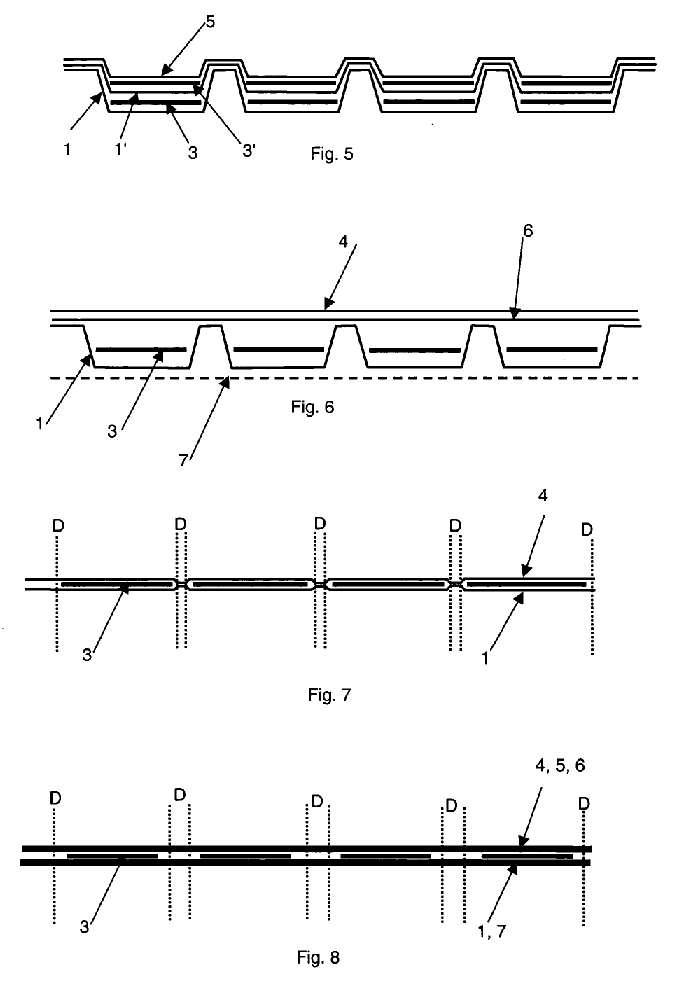

FIG. 5 shows an embodiment with two superimposed trays.

FIG. 6 shows an embodiment with supplementary sheets.

FIG. 7 shows a view of a section of the assembly after pressing.

FIG. 8 shows a view of a section of the assembly after pressing with several superimposed sheets.

FIG. 1 shows a general view of the first insulating sheet (1) in form of a tray constituting the base element for the conditioning and handling of electronic components provided with cells (2) containing each a transponder (3). The cells (2) are, in general, adapted to the size and the shape of their contents. This tray is introduced like it is with the components (3) in the manufacturing process of the modules. The two first steps of the method that would consist, on one hand, in preparing a first sheet then on the other hand, placing the components properly on this sheet, are thus suppressed.

FIG. 2 shows a section according to the axis A-A of the first insulating sheet (1) whose cells (2) contain the transponder (3).

FIG. 3 shows the first step of the shortened method that consists in superimposing a second sheet (4) onto the first insulating sheet (1) in order to close all the cells (2) containing a transponder (3). This second sheet can include an auto-adhesive layer of material on the internal face applied onto the first sheet (1).

According to an embodiment of the method, the cells can be filled with a resin before the assembly of the second insulating sheet (4) in order to encapsulate the electronic component (3).

FIG. 4 shows an embodiment where the second sheet (5) includes cells obtained by thermoforming. The size of these cells is chosen in such a way that these cells can fit into the cells (2) of the conditioning element (1) when the second sheet (5) is superimposed onto the first one (1). This second sheet (5) can also be a second tray of electronic components whose cells are empty.

FIG. 5 shows another embodiment where two trays (1, 1′) containing an electronic component (3, 3′) are superimposed. The second tray is covered by a cell sheet (5) as in FIG. 4. This example shows that several trays containing components can be stacked in such a way that the cells fit into one another. The last tray is covered by a sheet including cells or not (see FIG. 3).

For example, this kind of configuration is advantageously used for manufacturing modules having several transponders each functioning at a different frequency.

FIG. 6 shows an example of realisation where a sheet (6) is added between the conditioning element (1) and the second sheet (4). A supplementary sheet (7) can also be assembled on the opposite side of the assembly. The number of supplementary sheets assembled on the faces of the module is not limited. They contribute in increasing the thickness and the rigidity of the module necessary for certain applications. The intermediate sheets or those last assembled can include a decoration or a marking allowing identification of the modules after their cutting in the pressed plate. Furthermore, one or the other of the sheets constituting the external faces of the final module can include a layer of auto-adhesive material intended to stick the module on the surface of any support. In this case, such a module constitutes, for example, an electronic label for the identification of an object.

In another embodiment, the used sheets (4, 5, 6) can include transparent areas playing the role of windows allowing all or part of the transponder or the component to be visible. In an embodiment, certain intermediate sheets can include openings that are, in general, covered by transparent areas of external sheets or by completely transparent sheets. These openings are made in the area where the component is located in order to let it appear completely, partially or in parts distributed on the surface of the module. This property allows one to distinguish an authentic transponder module from an imitation not including any component.

In the embodiment where a filling resin is used during the manufacturing the modules it will be transparent in order to allow the electronic component/s to be visible.

This security aspect is exploited, for example, in the access control applications where the modules are used as tickets, name tags or pre-paid cards. Furthermore adequate marking, holograms, logos, etc. allow reinforcing module protection against piracy.

FIG. 7 shows the assembly after hot pressing of the base sheet (1), transponders (3) and recovery sheet (4).

The product thus obtained is a thin plate formed by the juxtaposition of two sheets (1, 4) between which the transponders (3) are encapsulated. The electronic modules are then cut in the plate according to a predefined outline in the areas (D) separating the cells. The sheets mould the components after pressing because of their slight thickness. This kind of realisation is for example suitable for electronic label intended to be stuck onto objects.

FIG. 8 shows an assembly after hot pressing several sheets superimposed on each face (1, 4, 5, 6, 7), between which the transponders (3) are located. The product thus obtained is a thick, rigid plate with sensibly flat faces. This embodiment applies for example to the manufacturing of nametags, keys or smart cards.

All the insulating sheets used in the manufacturing process of the modules can include openings (holes, slots) and/or relief structures (grooves, channels, embossing) used for the evacuation of the air imprisoned in the cells during the pressing operations. In fact, the air escapes through the openings and/or laterally through the edges of the plate thanks to relief structures, which avoids the formation of undesirable bubbles on the surface of the modules.

In the embodiment where a filling resin is used for manufacturing the modules, the openings or the relief structures of the insulating sheets are also used for the evacuation of the surplus resin out of the cells during the pressing.

1-22. (canceled)

23. Method for manufacturing an electronic module having at least one electronic component (3) transported on a tray made for the handling of electronic components and comprising cells (2), and a second insulating sheet characterized by the following steps:
placing the cells tray forming a first insulating sheet (1) on a work surface, said cells (2) containing each at least one electronic component (3),
superimposing the second insulating sheet (4) onto the first in such a way as to close the cells (2) containing the electronic component (3),
cutting the modules according to an outline including at least one cell (2) of the first insulating sheet (1).

24. Method according to claim 23 characterized in that the second insulating sheet (4) includes a layer of auto-adhesive material on the face intended to be applied onto the first insulating sheet (1).

25. Method according to claim 23 characterized in that a step of hot pressing of the assembly constituted by the superimposing of the second insulating sheet (4) onto the first insulating sheet (1) is carried out by means of a pressing plate applied onto the second insulating sheet (4).

26. Method according to claim 23 characterized in that a filling material is introduced into the cells containing the electronic component before the superposition of the second insulating sheet (4), said material encapsulating the electronic component.

27. Method according to claim 23 characterized in that the second insulating sheet includes cells, said cells fitting into the cells (2) of the first insulating sheet (1) at the time of superimposing the second sheet onto the first one (1),

28. Method according to claim 27 characterized in that the second sheet (5) constitutes a second tray of electronic components (3) whose cells are free of electronic components.

29. Method according to claim 23 characterized in that at least one supplementary sheet (6, 7) is placed onto the first and/or second sheet (4, 5) said supplementary sheet serving as decoration and/or reinforcement of the module.

30. Method according to claim 23 characterized in that a plurality of cells trays (1, 1′) containing electronic components (3, 3′) is stacked, the cells (2) of a tray fit into the cells of the previously placed tray, said stack is covered by a sheet (4, 5) closing the cells of the last tray of said stack.

31. Method according to claim 25 characterized in that the sheets constituting the assembly include openings and/or relief structures, said openings and/or structures assuring the evacuation of the air imprisoned in the cells (2) during the pressing operation.

32. Method according to claim 31 characterized in that the openings and/or relief structures assure the evacuation of the surplus filling material out of the cells (2) during the pressing operation.

33. Electronic module comprising an assembly of a first insulating sheet (1), of at least one electronic component (3) and of a second insulating sheet (4, 5) characterized in that the first insulating sheet (1) is constituted by a part of a tray of electronic components handling, said part including at least one cell (2), containing each at least one electronic component (3).

34. Module according to claim 33 characterized in that it includes a layer of filling material between the first and the second insulating sheet, said material encapsulating the electronic component/s (3).

35. Module according to claim 33 characterized in that at least one supplementary sheet (5, 6, 7) is assembled on one and/or the other face of the module, said supplementary sheet being able to include a decoration.

36. Module according to claim 33 characterized in that the second insulating sheet is constituted by a part of a second tray of electronic components handling, the cells of said second sheet being inserted into the cells of the first sheet are free of electronic components.

37. Module according to claim 33 including a stack of insulating sheets (1, 1′) constituted by parts of trays of electronic components handling, the cells of said trays being inserted into each other containing each a component (3, 3′), the last sheet of the stack being covered by a second sheet (4, 5).

38. Module according to claim 33 characterized in that one and/or the other of said insulating sheets (1, 4) include a decoration serving as an identification mark of the module.

39. Module according to any one of claims 33 to 38 characterized in that the thickness of the insulating sheets (1, 4, 5, 6, 7) determines the final thickness and rigidity of the module.

40. Module according to any one of claims 33 to 38 characterized in that the insulating sheets (1, 4, 5, 6, 7) include openings and/or relief structures intended for the evacuation of air and/or the surplus filling material during the pressing operation carried out when the module is manufactured.

41. Module according to any one of claims 33 to 38 characterized in that the insulating sheets (1, 4, 5, 6, 7) include transparent areas playing the role of windows allowing all or part of the electronic component (3) to be visible, said visibility of the component permitting authentication of the module.

42. Module according to claim 34 characterized in that the filling material is transparent assuring the visibility of the electronic component/s.

43. Module according to any one of claims 33 to 38 characterized in that the insulating sheets (1, 4, 5, 6, 7) include openings in the area where the electronic component (3) is located, said openings being covered by the transparent areas of the supplementary sheet (5, 6, 7), said areas being able to cover all or parts of the supplementary sheet and constituting the windows letting all or part of the electronic component (3) appear, said supplementary sheet being applied onto one and/or the other faces of the module.

44. Module according to claim 33 characterized in that one of the insulating sheets, constituting the external faces of the module, includes a layer of auto-adhesive material destined to fix the module onto the surface of a support.
